(19) United States
(12) Patent Application Publication
(10) Pub. No.: US 2017/0243971 A1
(43) Pub. Date: Aug. 24, 2017

(54) SEMICONDUCTOR DEVICE

(71) Applicant: KABUSHIKI KAISHA TOSHIBA, Tokyo (JP)

(72) Inventors: Kanako KOMATSU, Yokohama Kanagawa (JP); Takehito IKIMURA, Yokohama Kanagawa (JP)

(21) Appl. No.: 15/255,673

(22) Filed: Sep. 2, 2016

Related U.S. Application Data
(60) Provisional application No. 62/296,883, filed on Feb. 18, 2016.

(51) Int. Cl. H01L 29/78; H01L 29/10; H01L 29/36; H01L 29/06

(52) U.S. Cl. CPC H01L 29/7816; H01L 29/0649; H01L 29/1095; H01L 29/36

(57) ABSTRACT

According to one embodiment, the gate insulating film is provided on a semiconductor region including the body region and the drift region between the source region and the drain region. The gate insulating film includes a first part and a second part. The first part is provided on the source region side. The second part is provided on the drain region side and thicker than the first part. The insulating portion is provided in the semiconductor region under a boundary between the first part and the second part of the gate insulating film.

### CROSS-REFERENCE TO RELATED APPLICATION

This application is based upon and claims the benefit of priority from U.S. Provisional Patent Application 62/296,883, filed on Feb. 18, 2016; the entire contents of which are incorporated herein by reference.

### FIELD

Embodiments described herein relate generally to a semiconductor device.

### BACKGROUND

Both low ON resistance and high static breakdown voltage are desirable for a power device such as a double-diffused metal-oxide-semiconductor (DMOS) device.

### BRIEF DESCRIPTION OF THE DRAWINGS

FIG. 1 is a schematic cross-sectional view showing a semiconductor device according to an embodiment;

FIG. 2 is a schematic planar view showing a planar layout of a portion of components of the semiconductor device according to the embodiment;

FIG. 3 is a schematic cross-sectional view showing a semiconductor device according to a modification of the embodiment;

FIG. 4 is a schematic cross-sectional view showing a semiconductor device according to a modification of the embodiment; and

FIG. 5 is a schematic cross-sectional view showing a semiconductor device according to another embodiment.

### DETAILED DESCRIPTION

According to one embodiment, a semiconductor device includes a source region of a first conductivity type, a drain region of the first conductivity type provided to be separated from the source region, a body region of a second conductivity type provided between the source region and the drain region, a drift region of the first conductivity type provided between the body region and the drain region, a gate insulating film, a gate electrode provided on the gate insulating film, and an insulating portion. A first conductivity type impurity concentration is lower in the drift region than in the drain region. The gate insulating film is provided on a semiconductor region including the body region and the drift region between the source region and the drain region. The gate insulating film includes a first part and a second part. The first part is provided on the source region side. The second part is provided on the drain region side and thicker than the first part. The insulating portion is provided in the semiconductor region under a boundary between the first part and the second part of the gate insulating film.

Embodiments of the invention will now be described with reference to the drawings. In the drawings, similar components are marked with like reference numerals.

Although the case where the first conductivity type is an N-type and the second conductivity type is a P-type will be described in the following embodiments, it is possible to implement the embodiments in the case where the first conductivity type is the P-type and the second conductivity type is the N-type.

The semiconductor device according to the embodiment has, for example, a structure in which an analog IC and a power device are formed on the same substrate and mounted on one chip. The power device having a DMOS is described in the following embodiments.

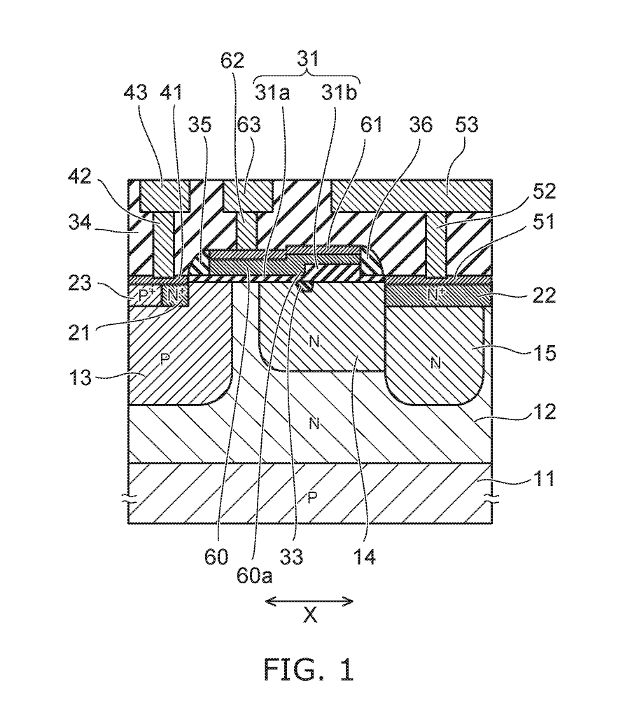

FIG. 1 is a schematic cross-sectional view showing the semiconductor device according to the embodiment

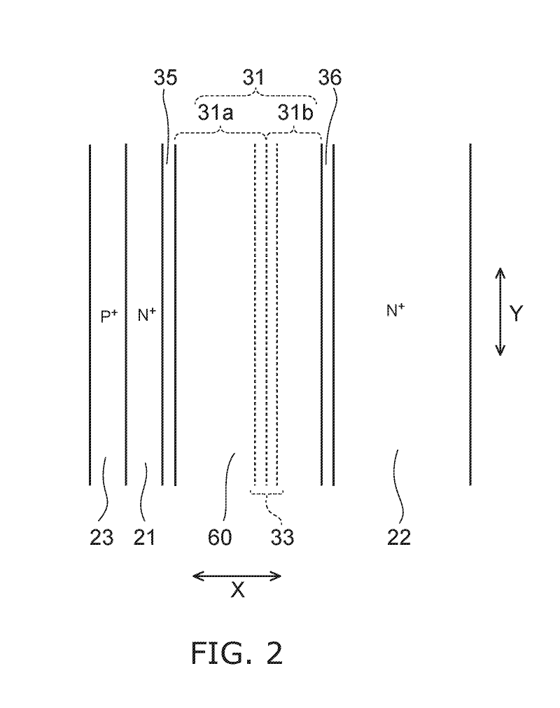

FIG. 2 is a schematic planar view showing a planar layout of a portion of the components of the semiconductor device according to the embodiment.

The semiconductor device according to the embodiment includes a substrate 11 and a semiconductor region that is provided on the substrate 11. These substrate 11 and semiconductor region can be collectively referred as a semiconductor layer. The substrate 11 is a semiconductor substrate and, for example, a P-type silicon substrate. The semiconductor region on the substrate 11 described below is also a silicon region doped with impurities.

The materials of the substrate 11 and the semiconductor region on the substrate are not limited as silicon but may be, for example, silicon carbide, gallium nitride, or gallium oxide.

An impurity concentration may be replaced with a carrier concentration in the following embodiments. The carrier concentration may be considered to be an effective impurity concentration.

As shown in FIG. 1, a deep well region 12 of the N-type is provided on the substrate 11. A body region 13 of the P-type, a drift region 14 of the N-type, and a well region 15 of the N-type are provided in the surface of the deep well region 12.

The drift region 14 is provided between the body region 13 and the well region 15. A direction connecting the body region 13 and the well region 15 is taken as X direction. The X direction corresponds to a gate-length direction of the semiconductor device according to the embodiment.

The drift region 14 contacts the well region 15. The bottom of the well region 15 is positioned deeper than the bottom of the drift region 14. A portion of the deep well region 12 is provided between the body region 13 and the drift region 14. The body region 13 may contact the drift region 14.

A source region 21 of the N-type and a back gate region 23 of the P-type are provided in the surface of the body region 13. The P-type impurity concentration in the back gate region 23 is higher than the P-type impurity concentration in the body region 13.

The source region 21 and the back gate region 23 contact with each other in the X direction. A P-N junction is formed between the body region 13 and the side surface of the source region 21 on a side opposite to the back gate region 23, and between the body region 13 and the bottom of the source region 21.

A portion of the body region 13 and a portion of the deep well region 12 are provided between the source region 21 and the drift region 14.

A drain region 22 of the N-type is provided in the surface of the well region 15. The N-type impurity concentration in the drain region 22 and the N-type impurity concentration in the source region 21 are higher than an N-type impurity concentration in the drift region 14. The N-type impurity concentration in the well region 15 is lower than the N-type impurity concentration in the drain region 22 and higher than the N-type impurity concentration in the drift region 14.

The bottom of the drain region 22 is positioned shallower than the bottom of the drift region 14 and the bottom of the well region 15. Widths of the drain region 22 and the well region 15 in the X direction are not limited as the relationship shown in the drawings. The width of the well region 15 may be wider than the width of the drain region 22; and the drain region 22 may be included in the surface of the well region 15. Or, the width of the drain region 22 may be wider than the width of the well region 15. Or, the end of the drain region 22 may be aligned with the end of the well region 15.

The source region 21 and the drain region 22 are separated in the X direction. A portion of the body region 13, a portion of the deep well region 12, and the drift region 14 are provided between the source region 21 and the drain region 22.

The back gate region 23, the source region 21, and the drain region 22 extend in a Y direction that intersects the X direction, as shown in FIG. 2.

A gate insulating film 31 is provided on a semiconductor region that includes the body region 13, the deep well region 12, and the drift region 14 between the source region 21 and the drain region 22.

The gate insulating film 31 is provided on the body region 13, the deep well region 12, and the drift region 14 between the source region 21 and the drain region 22.

The gate insulating film 31 includes a first part 31a and a second part 31b. The first part 31a is provided on the source region 21 side of the second part 31b, and the second part 31b is provided on the drain region 22 side of the first part 31a. The first part 31a and the second part 31b are continuous.

The first part 31a is provided on the body region 13, the deep well region 12, and a portion of the drift region 14 that is positioned on the source region 21 side of an insulating portion 33 described below.

The second part 31b is provided on the drift region 14 between the insulating portion 33 and the drain region 22.

The thickness of the second part 31b is thicker than the thickness of the first part 31a. The upper surface of the second part 31b is positioned higher than the upper surface of the first part 31a. A step is formed between the upper surface of the first part 31a and the upper surface of the second part 31b.

The boundary between the gate insulating film 31 and the semiconductor region is flat. In the example shown in FIG. 1, a thickness of the second part 31b of the gate insulating film 31 is substantially uniform in the X direction, and the upper surface of the second part 31b is flat.

A gate electrode 60 is provided on the gate insulating film 31. The gate electrode 60 is provided as one body on the first part 31a and the second part 31b of the gate insulating film 31.

In the example shown in FIG.1, a step is formed in the upper surface of the gate electrode 60 along the step in the upper surface of the gate insulating film 31. Or, the upper surface of the gate electrode 60 may be tapered on the second part 31b of the gate insulating film 31. A thickness of the gate electrode 60 on the second part 31b may gradually increase toward the drain region 22 side. Or, the upper surface of the gate electrode 60 may be flat.

The gate insulating film 31 and the gate electrode 60 extend continuously in the Y direction, as shown in FIG. 2.

A sidewall insulating film 35 is provided on the side surface (the end) of the gate electrode 60 on the source region 21 side. A sidewall insulating film 36 is provided on the side surface (the end) of the gate electrode 60 on the drain region 22 side. The sidewall insulating film 35 and the sidewall insulating film 36 extend continuously in the Y direction.

The gate electrode 60 includes, for example, polysilicon doped with impurities as a major component. A metal silicide film 61 is formed on the upper surface of the gate electrode 60.

A metal silicide film 51 is formed on the upper surface of the drain region 22.

A metal silicide film 41 is formed on the upper surface of the source region 21 and the upper surface of the back gate region 23.

An insulating layer 34 is provided on a semiconductor region (or a semiconductor layer) including the deep well region 12, the body region 13, the back gate region 23, the source region 21, the drift region 14, the well region 15, and the drain region 22.

The insulating layer 34 is also provided on the gate electrode 60, the sidewall insulating film 35, and the sidewall insulating film 36; and the insulating layer 34 covers the gate electrode 60, the sidewall insulating film 35, and the sidewall insulating film 36.

A source electrode (or a source interconnect) 43, a gate interconnect 63, and a drain electrode (or a drain interconnect) 53 are provided in the insulating layer 34 or on the insulating layer 34. A source contact 42, a gate contact 62, and a drain contact 52 are provided in the insulating layer 34.

The drain electrode 53 is connected to the metal silicide film 51 on the upper surface of the drain region 22 via the drain contact 52. Therefore, the drain region 22 is electrically connected to the drain electrode 53.

The gate interconnect 63 is connected to the metal silicide film 61 on the upper surface of the gate electrode 60 via the gate contact 62. Therefore, the gate electrode 60 is electrically connected to the gate interconnect 63.

The source electrode 43 is connected to the metal silicide film 41 on the upper surface of the source region 21 via the source contact 42. Therefore, the source region 21 is electrically connected to the source electrode 43.

The source electrode 43 also functions as a back gate electrode. The source electrode 43 is connected to the metal silicide film 41 on the upper surface of the back gate region 23 via the source contact 42. Therefore, the electric potential of the source electrode 43 is applied to the body region 13 via the back gate region 23.

An insulating portion 33 is provided in the drift region 14 under a boundary between the first part 31a and the second part 31b of the gate insulating film 31. The insulating portion 33 has shallow trench isolation (STI) structure in which an insulating film is buried in a shallow trench formed in the surface of the drift region 14.

The insulating portion 33 protrudes toward below the gate insulating film 31. The thickness of the insulating portion 33 (the protruding length into the drift region 14) is smaller than the thickness (the depth) of the drift region 14. The thickness of the insulating portion 33 is smaller than the distance between the bottom of the insulating portion 33 and the bottom of the drift region 14. The boundary between the gate insulating film 31 and the drift region 14 is positioned higher than the bottom of the insulating portion 33.

The insulating portion 33 does not contact the drain region 22 and the well region 15. The drift region 14 exists between the insulating portion 33 and the drain region 22.

The insulating portion 33, as shown in FIG. 2, extends in the Y direction under the boundary between the first part 31a and the second part 31b of the gate insulating film 31.

The semiconductor device according to the embodiment is turned on by applying a desired gate electric potential to the gate electrode 60 in which a first electric potential is applied to the drain region 22 and a second electric potential lower than the first electric potential is applied to the source region 21. An inversion layer (an n-channel) is induced in the surface of the body region 13 of P-type adjacent to the source region 21. A current flows between the drain electrode 53 and the source electrode 43 through the drain region 22, the surface of the drift region 14, the surface of the deep well region 12 between the drift region 14 and the body region 13, the n-channel in the surface of the body region 13, and the source region 21.

The drift region 14 having a lower N-type impurity concentration than the drain region 22 is depleted in a gate-off state in which the inversion layer is not induced in the surface of the body region 13; and the static breakdown voltage is increased.

The well region 15 of the N-type has an N-type impurity concentration between the N-type impurity concentration in the drain region 14 and the N-type impurity concentration in the drain region 22; and the well region 15 is provided between the drift region 14 and the drain region 22. This well region 15 suppresses a decrease of the static breakdown voltage caused by an abrupt change of an impurity concentration from the drift region 14 to the drain region 22.

Typically, in the DMOS device, a portion where the electric potential distribution becomes dense and the electric field strength becomes high is generated in the interior of the semiconductor region under the end portion of the gate electrode on the drain region side. This may decrease the static breakdown voltage in the gate-off state.

In the semiconductor device according to the embodiment, the thickness of the second part 31b of the gate insulating film 31 which is positioned on the drain region 22 side is increased more than the first part 31a which is positioned on the source region 21 side. By such a structure, a portion where the electric potential distribution becomes dense can be generated not in the interior of the semiconductor region but in the thickened second part 31b of the gate insulating film 31. This relaxes the electric field strength in the interior of the semiconductor region and increases the static breakdown voltage.

A corner 60a of the gate electrode 60 exists on the portion of the gate insulating film 31 at which the thickness changes. A portion where the electric potential distribution becomes dense is generated easily in the interior of the semiconductor region under the corner 60a of the gate electrode 60.

According to the embodiment, the insulating portion 33 of STI structure is provided in the drift region 14 under the boundary between the first part 31a and the second part 31b. The thickness of the gate insulating film 31 changes at the boundary. In other words, the insulating portion 33 exists under the corner 60a of the gate electrode 60. A portion where the electric potential distribution becomes dense can be generated at the insulating portion 33. This also relaxes the electric field strength in the interior of the semiconductor region and increases the static breakdown voltage.

The position and the thickness (the depth) of the insulating portion 33 are limited so that the insulating portion 33 does not interrupt an on-current flow which flows in the surface of the drift region 14. An increase of the current path length by which the on-current flows under the insulating portion 33 does not cause an increase of the on-resistance that is problem for practical use.

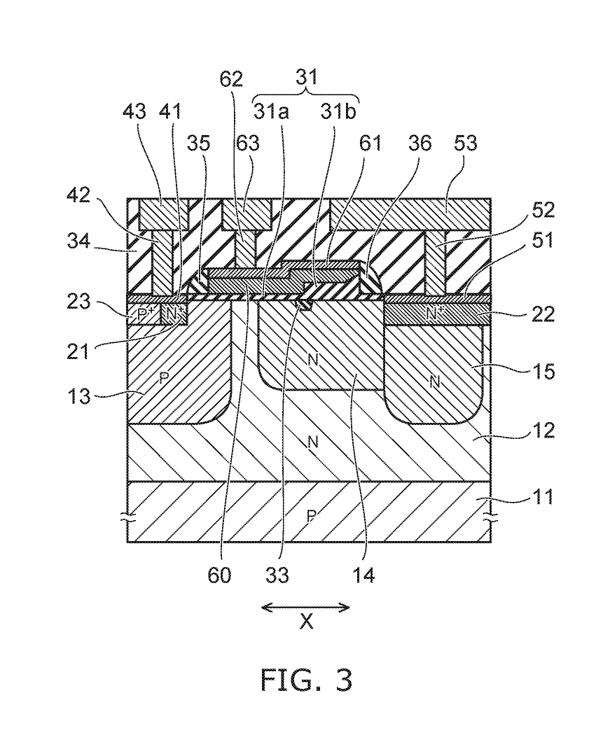

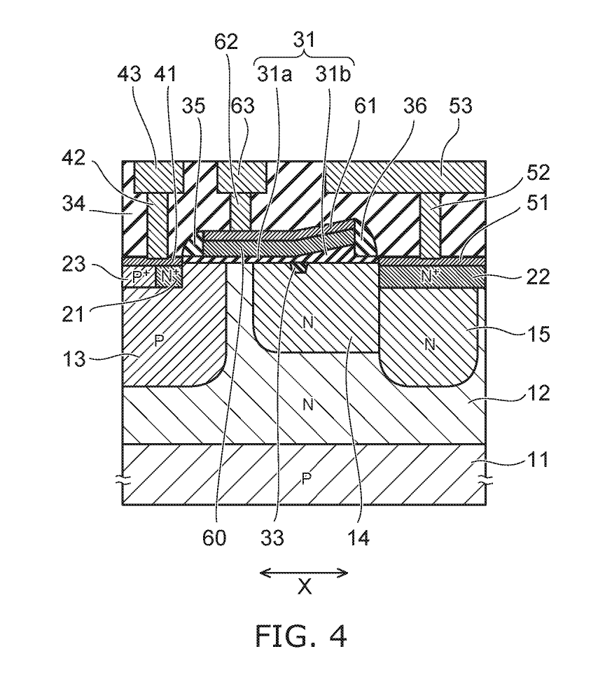

FIG. 3 and FIG. 4 are schematic cross-sectional views showing other structural examples of the second part 31b of the gate insulating film 31.

In the example shown in FIG. 3, in the second part 31b of the gate insulating film 31, the end portion on the drain region 22 side is thicker than the portion on the insulating portion 33.

In the example shown in FIG. 4, the thickness of the second part 31b of the gate insulating film 31 gradually increases from the boundary between the first part 31a and the second part 31b which is positioned on the insulating portion 33 toward the drain region 22 side.

In the examples shown in FIG. 3 and FIG. 4, the thickness of the second part 31b of the gate insulating film 31 is not uniform, but the thickness of the portion on the drain region 22 side where the electric field strength becomes easily high relatively increases. Thus, the structures shown in FIG. 3 and FIG. 4 are more effective to relax the electric field strength at the portion in the semiconductor region that is positioned at the vicinity of the end portion of the gate electrode 60 on the drain region 22 side.

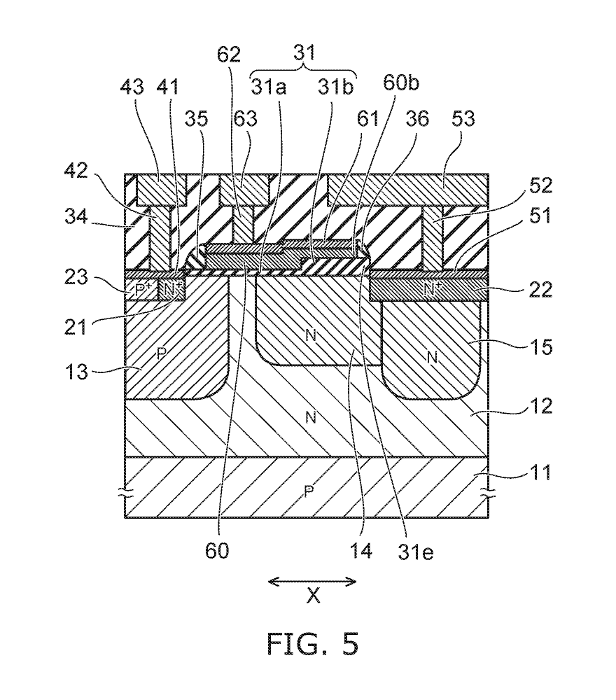

FIG. 5 is a schematic cross-sectional view showing a semiconductor device according to another embodiment. In FIG. 5, components similar to those in the semiconductor device shown in FIG. 1 are marked with like reference numerals, and a detailed description is omitted.

The second part 31b of the gate insulating film 31 includes an end portion 31e that is positioned on the drain region 22 side. The end portion 31e protrudes toward the drain region 22 side more than the end (the side surface) of the gate electrode 60 on the drain region 22 side. The end portion 31e of the second part 31b is positioned on the drain region 22 side of the end on the drain region 22 side of the gate electrode 60.

The gate electrode 60 is not provided on the end portion 31e, but the sidewall insulating film 36 is provided on the end portion 31e. The sidewall insulating film 36 covers the end of the gate electrode 60 on the drain region 22 side.

The end portion 31e that is a portion of the thickened second part 31b exists between the semiconductor region and the corner 60b of the gate electrode 60 on the drain region 22 side. A portion where the electric potential distribution becomes dense can be generated at the end portion 31e. This relaxes the electric field strength in the interior of the semiconductor region and increases the static breakdown voltage.

By the semiconductor devices according to the embodiments described above, both high breakdown voltage and low on-resistance can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a source region of a first conductivity type;
a drain region of the first conductivity type provided to be separated from the source region;
a body region of a second conductivity type provided between the source region and the drain region;
a drift region of the first conductivity type provided between the body region and the drain region, a first conductivity type impurity concentration being lower in the drift region than in the drain region;
a gate insulating film provided on a semiconductor region including the body region and the drift region between the source region and the drain region, the gate insulating film including a first part and a second part, the first part being provided on the source region side, the second part being provided on the drain region side and thicker than the first part;
a gate electrode provided on the gate insulating film; and
an insulating portion provided in the semiconductor region under a boundary between the first part and the second part of the gate insulating film.

2. The semiconductor device according to claim 1, wherein an upper surface of the second part of the gate insulating film is flat.

3. The semiconductor device according to claim 1, wherein the second part of the gate insulating film having an end portion on the drain region side and a portion on the insulating portion, the end portion on the drain region side is thicker than the portion on the insulating portion.

4. The semiconductor device according to claim 1, wherein a thickness of the second part of the gate insulating film gradually increases from a portion on the insulating portion toward the drain region side.

5. The semiconductor device according to claim 1, wherein the insulating portion protrudes toward below the gate insulating film.

6. The semiconductor device according to claim 1, wherein a boundary between the gate insulating film and the semiconductor region is positioned higher than a bottom of the insulating portion.

7. The semiconductor device according to claim 1, wherein the insulating portion continuously extends in a second direction intersecting a first direction that connects between the drain region and the source region.

8. The semiconductor device according to claim 1, wherein the insulating portion is provided in the drift region.

9. The semiconductor device according to claim 8, wherein a thickness of the insulating portion is thinner than a thickness of the drift region.

10. The semiconductor device according to claim 8, wherein a thickness of the insulating portion is smaller than a distance between a bottom of the gate insulating portion and a bottom of the drift region.

11. The semiconductor device according to claim 1, wherein the drift region contacts the drain region.

12. The semiconductor device according to claim 11, further comprising a first well region of the first conductivity type provided under the drain region, the first well region being in contact with the drain region and the drift region,
a first conductivity type impurity concentration in the first well region being lower than a first conductivity type impurity concentration in the drain region and being higher than a first conductivity type impurity concentration of the drift region.

13. The semiconductor device according to claim 1, wherein the source region is provided in a surface of the body region.

14. The semiconductor device according to claim 13, further comprising a back gate region of the second conductivity type provided in the surface of the body region, the back gate region being in contact with the source region.

15. The semiconductor device according to claim 1, further comprising:
a substrate of the second conductivity type; and
a second well region of the first conductivity type provided on the substrate,
the body region and the drift region provided in a surface of the second well region.

16. The semiconductor device according to claim 15, wherein a portion of the second well region is provided between the body region and the drift region.

17. A semiconductor device, comprising:
a source region of a first conductivity type;
a drain region of the first conductivity type provided to be separated from the source region;
a body region of a second conductivity type provided between the source region and the drain region;
a drift region of the first conductivity type provided between the body region and the drain region, a first conductivity type impurity concentration being lower in the drift region than in the drain region;
a gate insulating film provided on a semiconductor region including the body region and the drift region between the source region and the drain region, the gate insulating film including a first part and a second part, the first part being provided on the source region side, the second part being provided on the drain region side and thicker than the first part; and
a gate electrode provided on the gate insulating film,
the second part of the gate insulating film including an end portion that is positioned on the drain region side of an end of the gate electrode on the drain region side.

18. The semiconductor device according to claim 17, further comprising a sidewall insulating film provided on the end portion of the second part of the gate insulating film, the sidewall insulating film covering the end of the gate electrode on the drain region side.
